(19) United States
(12) Patent Application Publication
(10) Pub. No.: US 2018/0135165 A1
(43) Pub. Date: May 17, 2018

(54) A METHOD AND A DEVICE FOR COATING AN ENDOPROSTHESIS HAVING A BASE BODY

(71) Applicant: BIOTRONIK AG, Buelach (CH)

(72) Inventors: Christian Schwarz, Reinshagen Satow (DE); Enrico Buchholz, Elmenhorst (US); Carsten Momma, Rostock (DE)

(21) Appl. No.: 15/315,683

(22) PCT Filed: Jun. 24, 2015
(86) PCT No.: PCT/EP2015/064187

§ 371 Date: Dec. 1, 2016

(30) Foreign Application Priority Data
Jul. 16, 2014 (EP) 14177189.9
Jul. 16, 2014 (EP) 14177190.7

(51) Int. Cl. C23C 16/02; C23C 16/32; C23C 16/458; C23C 16/517; H01J 37/32

(52) U.S. Cl. CPC C23C 16/0245; C23C 16/0272; C23C 16/325; C23C 16/458; C23C 16/517; H01J 37/32715; H01J 37/32403; H01J 37/32412; H01J 37/32422; H01J 37/32706; H01J 37/32366

(57) ABSTRACT

The invention relates to a method for the plasma treatment of an endoprosthesis having base body. The method includes inserting the base body into a vacuum chamber; executing a cleaning step with a plasma treatment of a surface of the base body that is to be coated; executing a treatment step in a plasma of the surface of the base body that is to be coated, wherein ions out of the plasma are implanted into an area of the base body that is close to the surface.

The invention relates to a method and a device for coating an endoprosthesis having a base body. Further, the present invention relates to an endoprosthesis.

### BACKGROUND

Medical implants that can be inserted into the human body or the body of an animal must have sufficient biocompatibility. Such implants are, for example, stents and the like. In order to establish the biocompatibility of the implant, it is a known practice to provide implants of this type with a coating.

Nowadays, stents for the treatment of stenosis are used particularly often. They have a body in the form—where applicable—of an open work tubular or hollow cylindrical scaffold that is open at both longitudinal ends. The tubular scaffold of such an endoprosthesis is inserted into the vessel to be treated for the purpose of supporting the vessel. In particular, stents have established themselves for the treatment of vascular diseases. By using stents, narrowed sections in the vessels can be widened resulting in a gain of lumen. Although by using stents or other implants a most importantly required optimal vascular cross section can be achieved for a successful therapy, the permanent presence of a foreign body of this type initiates a cascade of microbiological processes that can lead to a gradual closing up of the stent and in the worst case, to vascular occlusion. One approach to solve this problem consists of producing the stent or other implants out of a biodegradable material.

Biodegradation refers to hydrolytic, enzymatic and other metabolic decomposition processes in a living organism that are caused primarily by the body fluids that come in contact with the biodegradable material of the implant and lead to a gradual dissolution of the structures of the implant containing the biodegradable material. As a result of this process, the implant loses its mechanical integrity at a certain point in time. The term biodegradation is often used synonymously with biocorrosion. The term bioresorption includes the subsequent resorption of the decomposition products by the living organism.

The materials suitable for biodegradable implants into the body can contain polymers or metals, for example. Thereby, the body can consist of several of these materials. The common property of these materials is their biodegradability. Examples of suitable polymeric compounds are polymers consisting of the group of cellulose, collagen, albumin, casein, polysaccharide (PSAC), polylactide (PLA), poly(1-lactide) (PLLA), polyglycol (PGA), poly(d 1-lactide-co-glycolide) (PDLLA-PGA), polyhydroxy butyric acid (PHB), polyhydroxy valeric acid (PHV), poly alkyl carbonate, polyorthoester, polyethylenterephtalate (PET), polymalonic acid (PML), polyanhydride, polyphosphazene, polyamino acids and their copolymers as well as hyaluronic acid. Depending on the desired properties, the polymers can be present in pure form, in derivatized form, in the form of blends or as copolymers. Metallic, biodegradable materials are based primarily on the alloys of magnesium and iron.

When producing biodegradable implants, the aim is to control the degradability in accordance with the desired therapy or the application of the respective implant (coronary, intracranial, renal, etc.). For example, an important target corridor applies to many therapeutic applications in which the implant loses its integrity within a period of four weeks to six months. Hereby, integrity, i.e. mechanical integrity, refers to the property of only marginal mechanical losses of the implant when compared with the non-degraded implant. This means that the implant continues to be mechanically stable to a degree that, for example, the collapse pressure is only marginal, i.e. it has decreased to 80% of its nominal value at most. Thus, the implant, at the integrity that is available, can meet its primary function, namely to keep the vessel open. Alternatively, the integrity can be defined by the mechanical stability of the implant at a level at which it has experienced hardly any geometric changes in its load condition in the vessel, for example, it does not noticeably collapse, i.e. it has at least 80% of the dilation diameter when subject to stress, or in the case of a stent, hardly any partially fractured support bars.

Frequently, CVD methods are used (CVD=Chemical Vapor Deposition), in particular, plasma-enhanced methods (PECVD; Plasma-Enhanced Chemical Vapor Deposition). Conventional coating methods have the inherent risk that the contact positions at which the implant is fastened during coating remain uncoated or that harmful flashovers are created in the plasma when stents come in contact with each other.

U.S. Pat. No. 5,238,866 A discloses a method and a device by means of which stents are coated with biocompatible materials.

U.S. Pat. No. 5,735,896 A discloses a method in which stents are coated with several hundred nanometers of silicon carbide (SiC) by means of PECVD.

Further, stopping the biodegradability of an implant by means of a suitable surface treatment is also known. EP 2 272 547 A1 discloses a tribo-chemical method in which an implant surface is sprayed with particles consisting of NaCl, CaCl, MgCl₂, Mg(OH)₂ and the like.

A problem in connection with coatings is given thereby that stents or other implants usually adopt two conditions, namely, a compressed condition with a small diameter and an expanded condition with a larger diameter. In compressed condition, the implant can be inserted into the vessel that is to be supported by means of a catheter and positioned at the location that is to be treated. At the treatment site, the implant is then dilated by means of a balloon catheter, or (when using a shape memory alloy as implant material) converted to an expanded condition by being heated to more than a transition temperature, for example. Based on this change in diameter, the body of the implant is hereby subjected to mechanical stress. Additional mechanical stresses impinging on the implant can occur during production, or when moving the implant within or with the vessel into which the implant has been inserted. Thus, the cited coatings have the disadvantage that the coating fissures during the deformation of the implant, for example, as the result of the formation of micro cracks, or is also sometimes removed. This can cause a non-specific local degradation. Moreover, the insertion and the speed of the degradation depends on the size and the distribution of the micro cracks formed by the deformation, and these are difficult to control as surface defects. This leads to a large variation of degradation times.

US 2011/0144761 A1 discloses a method in which a diffusion layer is formed on the surface of the base material to reduce the biodegradability, which can optimally also be coated with a metal layer and a passivation layer. To produce the diffusion layer, a corresponding coating is applied to the surface and diffused into it by means of a thermal treatment.

### SUMMARY OF THE INVENTION

A preferred embodiment of the invention provides a method for the plasma treatment of an endprosthesis including a base body, with a PECVD process having the steps:
inserting a base body into a vacuum chamber;
executing a cleaning step by means of a plasma treatment of a surface of the base body that is to be coated;
wherein the base body is positioned adjacent to a first electrode and at a distance to a second electrode in the cleaning step, and
   wherein the base body is electrically insulated with respect to the first electrode at least during the cleaning step.

The method may further include the step of
executing a treatment step on the surface of the base body that is to be coated in a plasma, whereby ions from the plasma are implanted in an area that is close to the surface of the base body.

Thereby, a side zone can advantageously be created in the bulk material of the base body that acts as diffusion barrier and can slow down the biodegradation of the bulk material. Thereby, the material used for the ion implantation on the surface can be selected as needed. Likewise, the diffusion layer can be structured in a targeted manner due to the parameters of the method. Furthermore, an additional layer can thereby be applied to the base body on the side zone.

In one embodiment, the method proposed herein includes the following treatment step:
Depositing a layer or series of layers with the help of a second electrode.

Advantageously, the present invention relates to implants whose biodegradable material contains at least some metal, preferably magnesium or a magnesium alloy. The base body preferably consists of magnesium or a biodegradable magnesium alloy.

Within the scope of the invention, the alloys and elements that are described as being biodegradable are those in which decomposition/restructuring takes place in a physiological environment so that the part of the implant consisting of the material is entirely, or at least primarily, no longer present.

### BRIEF DESCRIPTION OF THE DRAWINGS

In the following, the invention is explained in further detail by way of example with the help of the exemplary embodiments shown in the drawings. Shown in schematic representation are:

FIG. 1 shows a cross section of an exemplary embodiment of a coating device with an inserted endoprosthesis in the form of stents in an operating mode of direct voltage at a first electrode and an electrically insulated suspension of the stents;

FIG. 2 shows a schematic view of a stent;

FIG. 3 shows a view of a stent from FIG. 1 that rotates along with a rotating adapter of the device;

FIG. 4 shows a detail of the method during a cleaning step;

FIG. 5 shows a detail of the method in a treatment step in which ions are implanted into a surface of a base body;

FIG. 6 shows a detail of the method during a deposition step, and

FIG. 7 shows various distribution curves of implanted elements depending on an accelerating voltage.

In the Figures, functionally identical or identically acting elements are labeled with the same reference numbers respectively. The Figures are schematic illustrations of the invention. They do not show specific parameters of the invention. Furthermore, the Figures only reflect typical embodiments of the invention and shall not limit the invention to the illustrated embodiments.

### DETAILED DESCRIPTION OF THE PREFERRED EMBODIMENTS

In the case at hand, a magnesium alloy refers to a metallic structure in which the primary component is magnesium. The main component is the alloy component that has the largest weight component in the alloy. A component share of the main component is preferably more than 50% by weight, in particular more than 70% by weight. Preferably, the biodegradable magnesium alloy contains yttrium and additional rare earth metals, because an alloy of this type is marked by its physico-chemical properties and a high degree of biocompatibility, in particular, also its decomposition products. Particularly preferred is a magnesium alloy consisting of rare earth metals of 5.2-9.9% by weight, thereof yttrium 3.7-5.5% by weight and a residual of <1% by weight, whereby magnesium is the weight component needed to complete 100% of the alloy. This magnesium alloy has already confirmed its particular suitability in clinical trials, i.e. it shows a high degree of biocompatibility, favorable processing properties and good mechanical parameters and an adequate corrosion behavior for the intended use. In the case at hand, the collective name “rare earth metals” refers to scandium (21), yttrium (39), lanthanum (57) and the 14 elements following lanthanum (57), namely cerium (58), praseodymium (59), neodymium (60), promethium (61), samarium (62), europium (63), gadolinium (64), terbium (65), dysprosium (66), holmium (67), erbium (68), thulium (69), ytterbium (70) and lutetium (71). Furthermore preferred are magnesium alloys that contain up to 6% by weight of zinc.

Particularly preferred is a magnesium alloy consisting of yttrium 0.5-10% by weight, zinc 0.5-6% by weight, calcium 0.05-1% by weight, manganese 0-0.5% by weight, silver 0-1% by weight, cerium 0-1% by weight and zirconium 0-1% by weight or silicon 0-0.4% by weight, whereby the stated weight percentages refer to the alloy and magnesium and contaminants due to manufacturing conditions make up the remainder of the alloy up to 100% by weight.

The composition of the magnesium alloy must be selected in such a way that it is biodegradable, for example, a magnesium alloy having the composition (in % by weight) of 2.0% Zn, 0.8% Y and 0.25% Ca.

According to an advantageous embodiment, an ion implantation can be performed in the treatment step in such a way that a targeted distribution profile of the implanted ions is created in the area near the surface. In particular, a maximum of the distribution profile can be at a depth of the base body of at most 10 nm, in particular, at most 5 nm. Advantageously, any negative influences on the mechanical stability of the base body can be avoided due to the low depth.

According to an advantageous embodiment, at least one element of the group of elements having an atomic number between 5 and 50 can be implanted in the treatment step, in particular, from the group consisting of silicon, calcium, carbon.

Advantageously, the element to be implanted or the elements to be implanted are selected in such a way that they have an advantageous stabilization effect relative to biodegradation in conjunction with the material of the base body.

According to an advantageous embodiment, the base body is positioned adjacent to a first electrode and at a distance from a second electrode, in particular, in the cleaning step and/or treatment step and/or during a coating step. It is further proposed that the base body is electrically insulated during the cleaning step and/or the treatment step and/or a coating step. In particular, the base body is insulated relative to the first electrode. Further, the base body can be electrically insulated relative to the plasma. It is further proposed that in proximate position to the first electrode in the area of the base body an at least intermittently, practically electron-free side zone can be produced at least during the cleaning step and the treatment step, by applying a negative voltage as direct voltage or in pulsed manner to the first electrode. In a preferred embodiment it is therefore proposed that the method according to the invention includes the following step:
Producing an at least intermittently practically electron-free side zone in the gas chamber in proximate position to the first electrode in the area of the base body at least while cleaning the surface to be coated and/or the deposition of a layer or a series of layers.

The production of the at least intermittently electron-free side zone is accomplished by applying a negative voltage to the first electrode.

In the operating mode of plasma treatment, direct voltage can be applied at the first electrode while the base body or base bodies are in insulated mounting. As a result of the insulated mounting of the base bodies, e.g. endoprostheses such as, for example, stents, these are never placed onto electric potential directly. Thereby, any “burning” of the base bodies at small points of contact by holding elements for the base body can be avoided.

Additionally, the direct voltage at the base body is advantageous for a reduction of the integration of light elements such as, for example, the integration of hydrogen, and is particularly suitable for coating hydrophilic materials, in particular, for the coating of stents consisting of magnesium, magnesium alloys, nickel-titanium alloys (e.g. Nitinol) or the like. To a large extent, the base body that is to be coated can be protected from an undesired inclusion of hydrogen that could lead to embrittlement of the base body. For this, during plasma cleaning and/or during ion implantation and/or a coating, the voltage in the area of the base body can be adjusted suitably, whereby an at least intermittent, practically electron-free side zone can be created in proximate position to the first electrode.

Advantageously, as a result of the at least intermittently practically electron-free side zone in the area of the base body, it can be achieved that fewer hydrogen ions out of the plasma reach the base body that is to be coated so that it can charge itself slightly positive corresponding to the design of the at least intermittently practically electron-free side zone.

Moreover, the effect that that fewer hydrogen ions out of the plasma reach the base body is directly influenced by the insulated mounting of the base bodies since the insulated mounting results in only a slight positive charge of the base body which rejects hydrogen atoms but cannot reject heavier atoms. Thus, heavier ions reach the base body to be coated practically unimpeded in order to clean it during the plasma cleaning treatment or implant ions in the treatment phase or coat in a coating phase, while hydrogen ions are more likely to be deflected from such.

An advantageous frequency for charging the second electrode for the cleaning and/or for the deposition of an optional layer and/or an optional series of layers is, for example, 13.56 MHz.

According to an advantageous embodiment, a negative voltage can be applied to the first electrode. In an advantageous embodiment, the negative voltage can be larger at the start of the treatment step than at the end of the treatment step. Thereby, a depth distribution of the implanted element or of the implanted elements can be adjusted in a targeted manner.

Thereby, the voltage can be applied as continuous direct voltage or a pulsed direct voltage. The pulsed, negative voltage can be a pulsed voltage at a frequency of at most 1 MHz, preferably at most 400 kHz. In particular, according to an advantageous refinement of the method for creating the at least intermittently electron-free side zone, the first electrode can be charged in pulsed mode with a pulsed electric voltage. In particular, the voltage can be a pulsed, negative direct voltage. Due to the pulsed voltage, the body can develop an electric potential that attracts the positive ions, for example, argon ions during plasma cleaning. When using pulsed voltage, the stents are charged only slightly; a higher charge would be undesired in pulsed operating mode. A greater charge of the base body would be particularly disadvantageous because in the case of a potential that is too high, not only the light, positive ions, but also the heavy ions would be deflected. In such a case, neither a cleaning nor a coating of the base body would be given. Thus it was found to be particularly advantageous when the potential at the base body was adjusted in an advantageous range. Depending on the configuration of the system and the distance of the base body or base bodies to the first electrode, the adjustment can be variable. Further, it was found that a sufficiently long interval between the pulses is advantageous during which the body can discharge entirely or at least partially. The person skilled in the art will respectively select a suitable combination. Compared with the frequency of the voltage at the second electrode, the voltage at the first electrode is practically direct voltage. Advantageously, the pulsed voltage does not change signs. Advantageously, in pulsed mode, a pulse frequency can be between 1 kHz and 350 kHz, in particular, between 50 kHz and 100 kHz.

In particular, the continuous or pulsed electric voltage can be in the range between −1V and −2000V. An effective pulse voltage can be between −50 and −800V, in particular, between −500 and −800V.

An especially effective cleaning and simultaneous minimization of the integration of hydrogen is achieved in such a voltage range. Between pulses, there can be a pulse off time of 0.1 to 5 μs, in particular, between 1μs and 2 μs. In a preferred embodiment, an increase of the thickness of a layer on a base body can be charged in the three steps with a pulsed DC voltage having a frequency of 1-350 kHz, an off-time, i.e. intervals between the pulses of 0.1-5 μs, and a voltage of −50V to −800V, preferably having a frequency between 50 kHz to 100 kHz. An off-time of 1 μs to 2 μs and a pulse voltage of −500V to −800V is preferred. In the pulse off intervals, the potential is significantly lower or 0V. Advantageously, the base body is electrically insulated from the first electrode and can form an electric potential that attracts positive ions, for example, argon ions during plasma cleaning. These can charge the base body positively so that light hydrogen ions are repelled, but that heavy, positively charged ions are practically not influenced at all.

The penetration depth of elements in this voltage range, for example, silicon in stainless steel (e.g. L605), is under 10 nm. Advantageously, this voltage must be selected according to the thickness of the material of the base body so that the penetration depth of the element to be implanted is less than 10 nm. As a result of the insulated suspension of the base bodies, a selection of ions out of the plasma that reach the base body can be achieved in a targeted manner.

According to a favorable embodiment, a functional layer can be deposited on the surface of the base body, in particular, a functional layer consisting of silicon carbide or for example of diamond like carbon. The hard substance silicon carbide can reduce the biodegradation of the base body especially efficiently.

According to an advantageous refinement of the method, a holder can retain the body along its longitudinal axis. A plurality of adapters for a plurality of bodies can be provided that can, for example, be assembled parallel to each other. The bodies can be installed easily and securely.

According to an advantageous refinement of the method, the body can be rotated during the cleaning process of the surface to be coated and/or the deposition of the layer or series of layers in such a way that the body is coated on all sides. Advantageously, the adapter for the body can rotate. Even if the body is only placed loosely into the adapters, it can rotate along with it so that its surface can be coated all around. Even more complex surface structures such as those of a stent that does not have a two-dimensional surface, but has interlacing or meshing of wires, for example, can be coated reliably.

According to a further aspect of the invention, a device for executing a method for treating a base body, in particular an endoprosthesis, with a PECVD process is proposed in which a holder of the base body is electrically insulated from the plasma during the plasma cleaning step as well as in a treatment step, in which the surface of the base body is subjected to an ion implantation at a low depth.

According to a further aspect of the invention, an endoprosthesis is proposed, in particular, a stent having a base body consisting of magnesium or a magnesium alloy with a surface that was treated with ion implantation. In particular, an endoprosthesis is proposed, in particular, a stent having a base body consisting of magnesium or a magnesium alloy with a surface that was treated with a method as proposed herein, wherein the base body is electrically insulated with respect to the first electrode at least during the cleaning step resulting in a base body having a minimized or no hydrogen contamination.

Also advantageously, an area near the surface of the base body can be enriched with a chosen element, e.g. silicon. In a preferred embodiment, the surface of the base body can be provided with a layer consisting of at least one element from the group of elements having an atomic number between 5 and 50, in particular, from the group consisting of silicon, calcium, carbon. This has the advantage that the deposited layer in a layer sequence can function as adhesion-reinforcer for the layers above it. In an especially preferred embodiment, the surface of the base body can be coated with a layer of silicon. Also advantageous, the layer on the base body, e.g. of silicon, is deposited on a base body which has a minimized or no hydrogen contamination which is favorable for the adhesion and the durability of the layer as the base body has a reduced tendency to embrittlement.

Furthermore, silicon carbide can be deposited advantageously on the surface. As a result, the endoprosthesis releases significantly less magnesium than reference samples without an ion-implanted side zone and without a functional layer consisting of silicon carbide.

According to an advantageous refinement of the method, a layer sequence can be formed consisting of an adhesive layer and a functional layer. This can be accomplished without interrupting the vacuum and advantageously, even without interrupting the plasma.

According to an advantageous refinement of the method, the adhesive layer can consist of silicon and the functional layer of silicon carbide. In a preferred embodiment, an endoprosthesis, preferably a stent is proposed, preferably consisting of hydrogen depleted magnesium or a hydrogen depleted magnesium alloy with a surface that is treated by ion implantation including a layer sequence consisting of silicon on the endoprosthesis and silicon carbide on silicon. According to the present invention, amorphous silicon or amorphous silicon carbide is advantageous. During coating, the silicon carbide can also be implanted with suitable substances that can be integrated out of the plasma into the growing layer. In particular, an endoprosthesis is proposed, preferably a stent, that was produced according to a method proposed herein.

Advantageously, the invention allows a biocompatible coating of base bodies, in particular, implants such as stents or endoprostheses. The biocompatible coating and/or the base bodies thereby have a low to minimal, but at least not elevated, hence depleted, hydrogen content compared with untreated base bodies. Any hydrogen embrittlement of the base body can be avoided, which improves its long-term stability. In contrast, known methods lead to loading the basic material with hydrogen and this hydrogen content must always be controlled, because a hydrogen content that is too high leads to impairment of the material and thus to deterioration of the stent's function. Negative damage to the material due to local overheating of the material as the result of short circuits or electrical flashovers can likewise be avoided. The coating with a layer sequence can be accomplished in situ so that the base body does not have to be remounted. It is not possible to lose a stent during the process.

In the following, the invention is described with the help of the coating of stents. However, other types of endoprostheses are also conceivable such as, for example, cardiac valves and the like.

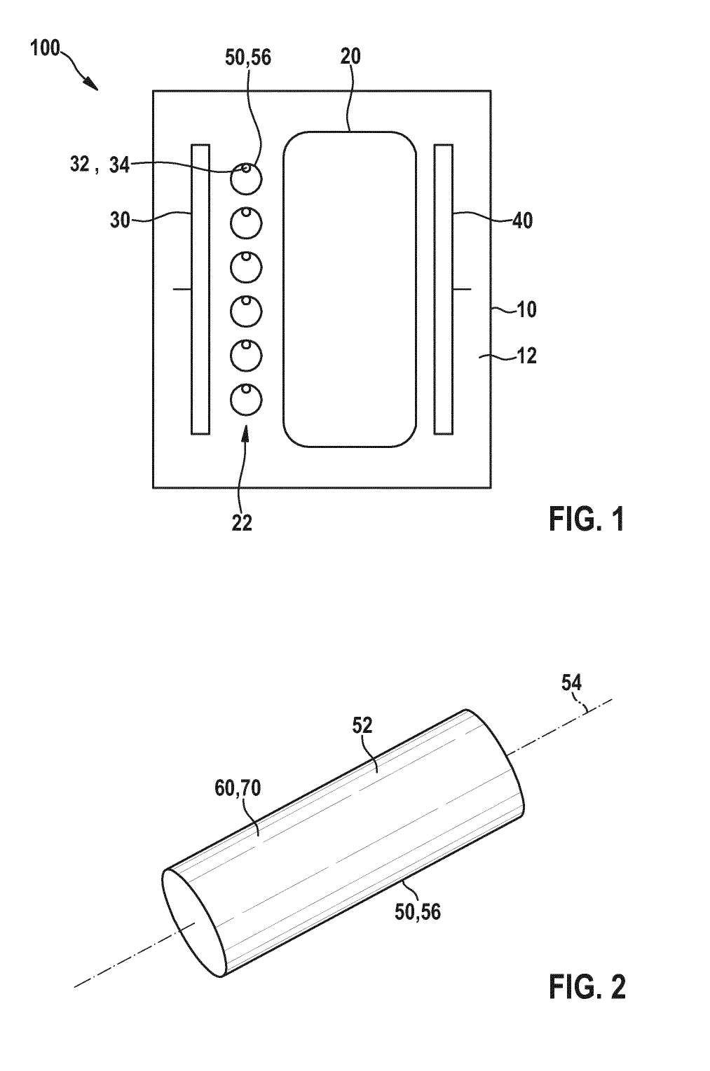

FIG. 1 shows a cross section in schematic view through an advantageous embodiment of a device 100 with a vacuum chamber 10 in which a number of base bodies 50 of stents 56 are located that are to be coated. PECVD methods are generally known so that conventional components such as gas delivery, gas supply, pumping units and the like are not shown. For example, a system like that in U.S. Pat. No. 5,238,866 A can be used. Reference to its disclosure is made herein in order to explain general prior art.

FIG. 2 shows a slanted view of a base body 50 in the form of a stent 56 whose surface 52 is treated in device 100 and is coated with a layer 60 or a series of layers 70. The stent 56 has a longitudinal extension with a longitudinal axis 54.

FIG. 1 shows the conditions during the cleaning step with a plasma cleaning process. In interior space 12 of the vacuum chamber 10, a high-frequency plasma 20 is ignited by means of which the surface of the stents 56 can be treated, in particular cleaned, implanted with ions and coated. In particular, this is a device 100 for executing a PECVD coating process with an HF-CCP plasma (CCP=Capacitively Coupled Plasma).

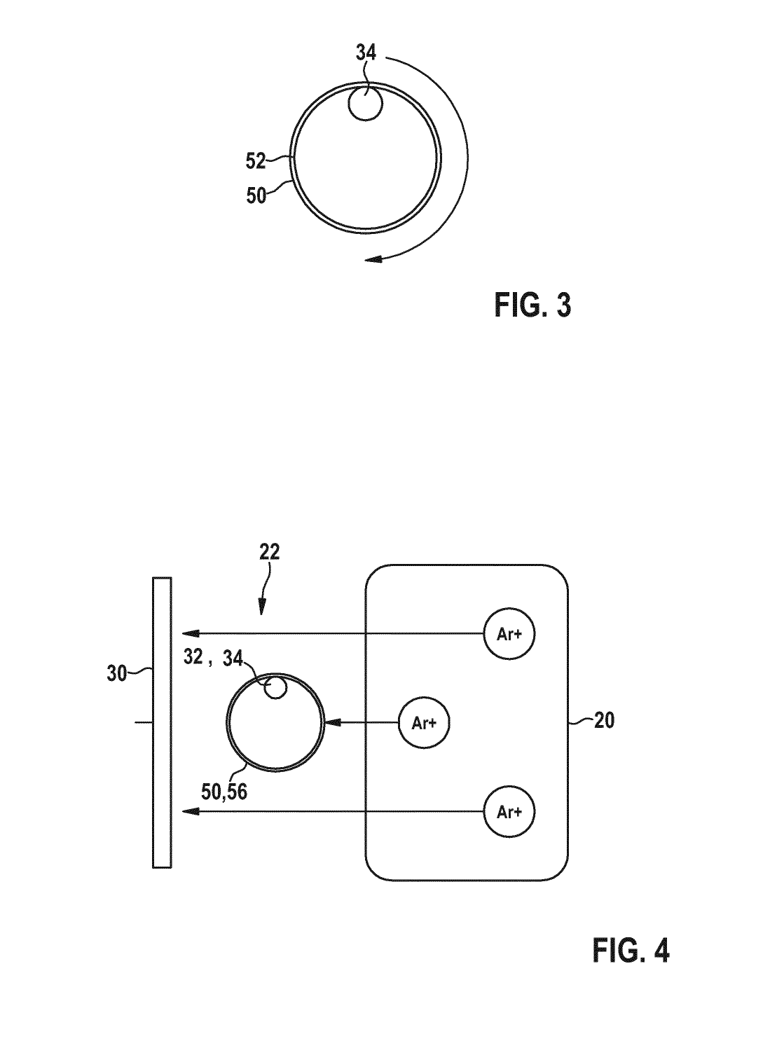

The stents 56 can be identified from their frontal side in a top view and extend perpendicular to the image plane. By way of example, six stents 56 are located on top of each other at holders 32. The stents 56 are placed onto bar-shaped adapters that extend transverse to the holders 32. The holders 32 make it possible to treat the surface of the stents 56 without shadowing effects on their surface, in particular, coat such. The adapters can rotate around their longitudinal axis as shown in FIG. 3. Even when the stents 56 only loosely abut with their interior circumference, they can still co-rotate so that their outer surfaces can be treated all-around. If the surface itself is permeable, even the inner surfaces can be co-treated.

The stents 56 are mounted electrically insulated and the electrode 30 is placed onto negative voltage. By being fired with positive ions, the stents 56 receive a low positive charge so that light ions (e.g. hydrogen) are subsequently deflected from the stents 56. The electrically insulated mounting of the stents 56 on rotatable holders is particularly preferred, as in the absence of insulation, a charge of the mounted stents can easily lead to electrical flashovers that can cause damage to the material and/or the stents come off the holders.

Furthermore, it is advantageous for the device proposed herein that the holders 32 are positioned adjacent to the first electrode 30 and at a distance to the second electrode 40. The first electrode is that electrode that provides a negative potential. The holders 32 are located adjacent to the first electrode 30 and at a distance to the second electrode when the holders in the space between the two electrodes are located closer to the first than to the second electrode. In particular, the holders 32 are located adjacent to the first electrode 30 and at a distance from the second electrode when the holders in the space between the electrodes are located in the half toward the first electrode, preferably in the third toward the first electrode and even further preferred, in the quarter toward the first electrode. Hereby, it is assumed that the space between the two electrodes can be divided into space segments by a theoretical plane—in the best case parallel to the two electrodes—whereby the two space segments that are created start at the respectively other electrode and meet in the theoretical plane.

Due to the configuration of the holders 32 adjacent to the first electrode 30 and at a distance to the second electrode 40, an electron-free side zone 22 can be created according to the invention that includes the holders and the base bodies located at such and/or the coated base body 50. As the result of the positioning of the holders 32 adjacent to the first electrode 30 and at a distance to the second electrode 40 the base bodies can thus be positively charged, even if the holders are electrically insulated.

The second electrode 40 is for the plasma-supporting treatment having a customary high frequency in the MHz range, e.g. 13.56 MHz. If corresponding precursor gases are fed into the vacuum chamber 10, e.g. silane, the precursor decomposes under the influence of the high-frequency plasma and a corresponding material, e.g. silicone deposits on surfaces in the plasma.

Due to the negative potential at the first electrode 30, an electron-depleted space 22 is created. Positive ions out of the surface section of the plasma 20 are accelerated toward electrode 30. Corresponding to the acceleration energy and the density of the base body 50, the ions can be inserted several nanometers into base body 50.

Essentially, a coating of the stents 56 with a layer or series of layers is accomplished in three steps. A plasma cleaning by means of an argon plasma is performed in a first step, as shown in FIG. 4. An ion implantation into an area close to the surface of the base body 50 takes place in a second step, a treatment step. Hereby, a diffusion barrier is formed at the surface of the base body 50.

In a third step a layer is applied, in a preferred embodiment, e.g. a silicon carbide layer, for example, an a-SiC:H:P layer or diamond like carbon as functional layer. For coating stents 56, in an embodiment an amorphous silicon layer as adhesive layer and a hydrogen-saturated and phosphor-doped silicon carbide layer is advantageous as functional layer.

Because the stents 56 are fixated on wires, they cannot build up due to the oscillations of the plasma. Thereby, the risk that adjacent stents 56 come in contact with each other and generate flashovers or even the loss of a stent can be reduced. The stents 56 can be packed much more densely on the holder so that the utilization of the coating space in the plasma 20 can be increased significantly. Thereby, a significant increase in productivity is possible.

The negative potential of the first electrode 30 attracts positive ions and these can charge the stents 56 positively to a slight degree. When using reactive gases that have a hydrogen component, the heavier, positively charged ions relative to hydrogen still reach the stents 56 and charge them positively, while the lighter hydrogen ions are repelled.

FIG. 3 shows the rotation of stent 56 from FIG. 1 on a rod-shaped or wire-shaped adapter 34. The stent 56 abuts only loosely on the adapter 34 and co-rotates when the adapter rotates around its longitudinal axis. Therefore, a coating can be accomplished that has a homogeneous thickness without shadowing effects or varying layer thickness. A deposition of two or more layers in a layer sequence can take place without moving the stents 56 in the vacuum chamber 10.

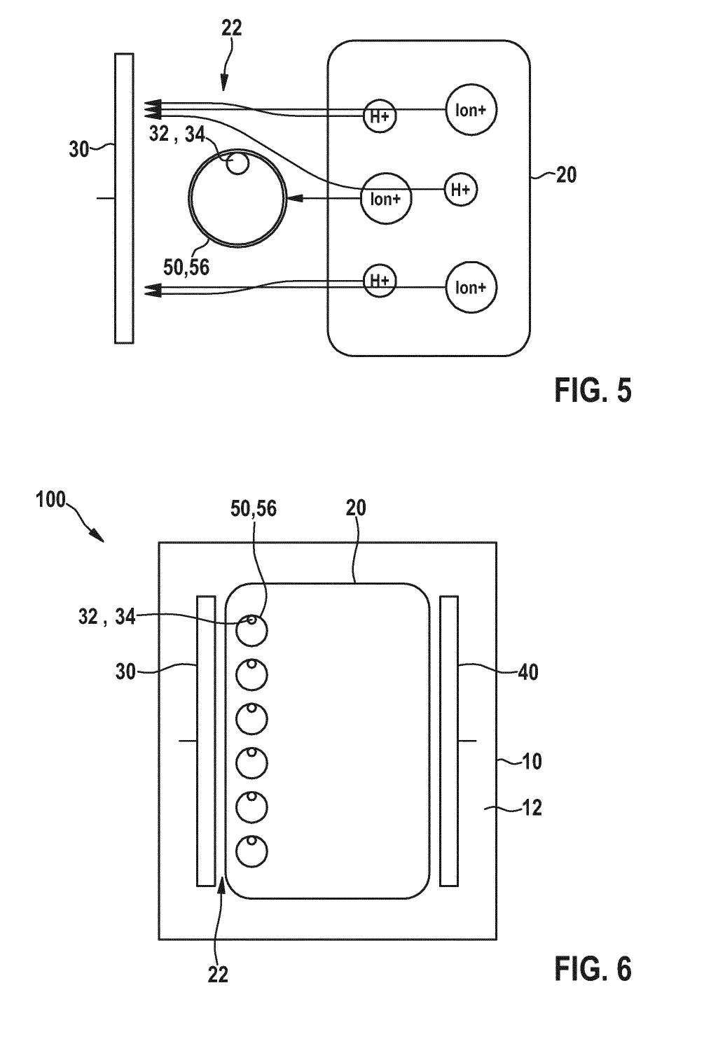

FIGS. 4 through 6 show various steps of the method described above for treatment with ion implantation and for coating the stents 56, whereby FIG. 4 shows a detail during plasma cleaning and FIG. 6 shows a detail during the deposition of the functional layer, while FIG. 5 shows an ion implantation step.

In this embodiment, the stents 56 (base bodies 50) are not electrically connected with the first electrode 30, but are electrically insulated with respect to the first electrode 30. The holder 32 with the stents 56 is located adjacent to the first electrode 30, at distance of approximately 1 cm to 2 cm, in particular, approximately 1.5 cm. Due to a slight positive charge of the stents 56 in the process, a deflection of hydrogen ions in the plasma can be achieved—away from the stents 56—and thus any embedding of hydrogen into the base material can be prevented.

To increase the layer adhesion, the deposition rate at the stents 56 to be coated and the reliability of the coating method, at least in the ion implantation treatment step, a constant DC voltage can be applied to the first electrode 30. A suitable DC voltage is, for example, in the range of several hundred to several thousand volt, e.g. between −500V and −2000V.

In order to prevent hydrogen loading, the stents 56 are placed or threaded onto insulated adapters 34. The first electrode 30 behind the stents 56 is placed onto a negative DC voltage. Due to the negative DC voltage, positive ions are accelerated out of plasma 20 in the direction of the first electrode 30 (in FIG. 4 argon ions, in FIG. 5 positive ions, e. g. silicon ions). Thereby, these ions also impinge on stents 56 leading to a slight positive charge of the stents 56. This charge is already sufficient for deflecting light hydrogen atoms, relatively heavy ions (e.g. Si, C, P) impinge on stents 56 in spite of that, whereby layer adhesion is ensured.

This charge can be started in the preceding cleaning step with argon gas already. Thereby, hydrogen embrittlement of the stent material can be prevented almost completely in the subsequent coating steps in which gases that have hydrogen components are used. In order to utilize this effect, a negative electric voltage of −500V to −2000V, preferably −1500V to −2000V, is applied to the first electrode 30 for an interval of 1 to 10 minutes, preferably 4 to 8 minutes. It was found that in the case of shorter intervals, the cleaning of the stent surface and the layer adhesion on the stent surface is insufficient. If the time interval and the voltage are selected to be too long and high, the electric charge of the stents 56 is too high so that undesirable discharge effects are generated in the form of electrical flashovers. For other types of systems or process conditions, respectively suitable parameters must be selected.

Advantageously, stents 56 are coated using a PECVD method in a device 100 by performing the steps of inserting the base body 50 into a vacuum chamber 10; positioning the base body 50 adjacent to a first electrode 30; cleaning the surface 52 of the base body 50 that is to be coated by means of a plasma treatment; deposition of a layer 60 or a sequence of layers 70 with the help of a second electrode 40; creating an at least intermittently practically electron-free side zone 22 in proximate position to the first electrode 30 in the area of the base body 50 at least during the cleaning process of the surface 52 that is to be coated and/or the deposition of the layer 60 or the sequence of layers 70.

During the coating of the stent surface 52, the voltage at the first electrode 30 is reduced, in particular, adjusted to 0V. Thereby, the stents 56 can discharge in the plasma 20 (FIG. 6).

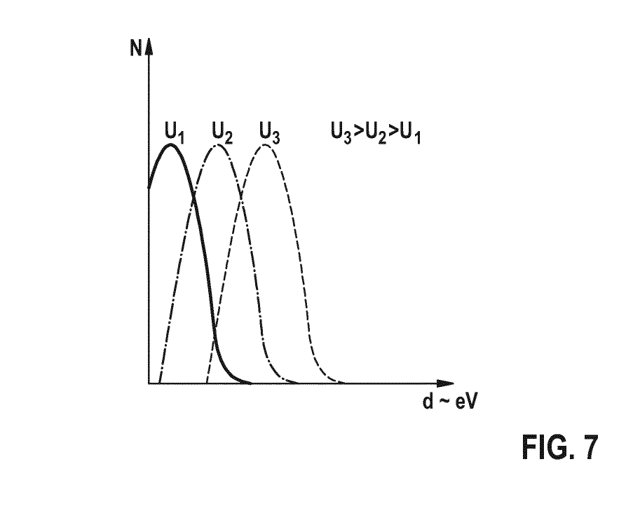

FIG. 7 shows a diagram with three different distribution curves of elements implanted at the surface depending on an acceleration voltage U for three different acceleration voltages U₁, U₂, U₃, whereby U₃>U₂>U₁. Thereby, the ordinate indicates a particle number, the abscissa the penetration depth. The penetration depth is proportional to the acceleration voltage at which the ions impinge on the target, i.e. the surface of base body 50. Thereby, the voltage varies, for example, between −250V and −2000V.

Thereby, the acceleration voltage is applied as negative voltage to the first electrode 30 (FIG. 5), so that positively charged ions are accelerated out of the plasma 20 (FIG. 5) in the direction of the first electrode 30, and on the way there impinge on the base body or the base bodies that are placed in proximate position to the first electrode. Typically, the distribution of the implanted particles is at least close to a Gaussian distribution. The smaller the acceleration voltage, the closer is the maximum of the distribution curve to the surface of the base body.

1. A method for the plasma treatment of an endoprosthesis having a base body with a PECVD (plasma enhanced chemical vapor deposition) process having the steps:
inserting a base body into a vacuum chamber;
executing a cleaning step by means of a plasma treatment of a surface of the base body that is to be coated;
wherein the base body is positioned adjacent to a first electrode and at a distance to a second electrode in the cleaning step, and
wherein the base body is electrically insulated with respect to the first electrode at least during the cleaning step.

2. The method according to claim 1 further comprising a step of
executing of a treatment step at the surface of the base body that is to be coated in a plasma, wherein ions out of the plasma are implanted in an area of the base body that is close to the surface.

3. The method according to claim 2, wherein an ion implantation in the treatment step is performed in such a way that a targeted distribution profile of the implanted ions is generated in the area close to the surface and that a maximum of the distribution profile is at a depth of at most 10 nm.

4. The method according to claim 2, wherein in the treatment step at least one element is implanted from the group of elements having an atomic number between 5 and 50.

5. The method according to claim 1, wherein prior to the first electrode in the area of the base body an at least intermittently practically electron-free side zone is created at least during the cleaning step and the treatment step by applying a negative voltage to the first electrode.

6. The method according to claim 5, wherein a negative voltage is applied to the first electrode.

7. The method according to claim 6, wherein the negative voltage is in a range of −1V and −2000V.

8. The method according to claim 7, characterized in that the negative voltage is a pulsed voltage having a frequency of at most 1 MHz.

9. The method according to claim 1, wherein on the surface (52) of the base body a functional layer is deposited.

10. A plasma enhanced chemical vapor deposition device for coating an endoprosthesis having a base body, comprising:
a vacuum chamber;
first electrode in the vacuum chamber;
a second plasma electrode in the vacuum chamber; and
an electrically insulated holder is to hold the endoprosthesis, the holder being closer to the first electrode then the second plasma electrode.

11. The device according to claim 10, comprising a plurality of holders.

12. The device according to claim 10, wherein the holder has a rotatable bearing for the endoprosthesis.

13. An endoprosthesis having a base body consisting of magnesium or a magnesium alloy having a surface that is treated with ion implantation.

14. The endoprosthesis according to claim 13, wherein an area of the base body that is close to the surface is enriched with silicon by ion implantation, and wherein on the surface, silicon carbide is deposited.

15. (canceled)

16. The method according to claim 2, wherein the maximum of the distribution profile is at a depth of at most 5 nm.

17. The method of claim 4, wherein the one element is from the group consisting of silicon, calcium and carbon.

18. The method of claim 6, wherein the negative voltage is larger towards the end than towards the beginning of the treating step.

19. The method of claim 8, wherein the pulsed voltage has a frequency of at most 400 kHz.
